(19) United States
(12) Patent Application Publication
(10) Pub. No.: US 2018/0059176 A1
(43) Pub. Date: Mar. 1, 2018

(54) OFFLINE VISION ASSIST METHOD AND APPARATUS FOR INTEGRATED CIRCUIT DEVICE VISION ALIGNMENT

(71) Applicant: Delta Design, Inc., Poway, CA (US)

(72) Inventors: Kexiang Ken Ding, San Diego, CA (US); Michael Anthony Laver, El Cajon, CA (US)

(73) Assignee: Delta Design, Inc., Poway, CA (US)

(21) Appl. No.: 15/686,964

(22) Filed: Aug. 25, 2017

Related U.S. Application Data
(60) Provisional application No. 62/380,330, filed on Aug. 26, 2016.

(51) Int. Cl. G01R 31/28; G01R 35/00; G01R 1/04

(52) U.S. Cl. CPC G01R 31/2891; G01R 1/0433; G01R 35/005

(57) ABSTRACT

An offline vision assisted calibration system includes: a bottom side socket assembly that is mountable in an integrated circuit device handler and comprises: a socket plate that comprises a hole grid array; and a top contactor assembly that is mountable in an integrated circuit device handler and comprises: a guide plate, a plurality of fiducials located on a lower side surface of the guide plate, a contact holder plate comprising a top contactor contact array, and a plurality of adjustment actuators configured to move the contact holder plate with respect to the guide plate; and a calibration jig comprising an array of contacts on a bottom side thereof, wherein the calibration jig is configured to be placed in the socket plate such that the contacts engage with the hole grid array of the socket plate.

### CROSS REFERENCE TO RELATED APPLICATION

The present application claims priority to U.S. Provisional Application No. 62/380,330, filed on Aug. 26, 2016, the contents of which are hereby incorporated by reference in their entirety.

### BACKGROUND OF THE INVENTION

This disclosure relates to the field of test equipment for integrated circuit (IC) devices. More particularly, this disclosure relates to an offline vision assisted method and apparatus for integrated circuit device vision alignment.

Semiconductor devices are commonly tested using specialized processing equipment. The processing equipment may be used to identify defective products and other various characteristics related to the performance of such devices. In most cases, the processing equipment possesses mechanisms for handling devices under test. In order to ensure accurate testing, handling mechanisms must be able to correctly align the device under test with various other testing tools and equipment. Correct alignment of the devices is important for efficient testing.

Various systems are used to position and align devices for testing, sorting and other functions. Generally, alignment is achieved using a mechanical alignment system. However, mechanical alignment is only accurate within certain manufacturing ranges and is not ideal for precise alignment operations. Further, modern devices with finer pitches are driving the need for optically assisted, or vision alignment as an alternative to mechanical alignment.

U.S. Pat. No. 7,842,912, assigned to the present applicant, describes a vision alignment system that includes one or more grouped alignment plates with guiding inserts configured to receive multiple devices, and groups of three actuators, configured to actuate the alignment plates to correct the position offsets of multiple devices as a group. The position offsets between the device and contactor are determined by a device-view camera during runtime and a contactor-view camera during calibration time. The vision alignment system also includes a pick-and-place handler, configured to transport devices. Other vision alignment systems are described in U.S. Pat. Nos. 7,506,451 and 8,106,349, also assigned to the present applicant. In the systems and methods described in these patents, vision calibration occurs at the test site. All of these patents are hereby incorporated by reference in their entireties.

### SUMMARY OF THE INVENTION

The systems of the above described patents are effective for performing vision alignment at the test site. However, for double-sided IC devices—that is, devices having both top and bottom side contacts—such as package on package (“POP”) devices, it would be advantageous to be able to perform alignment between a top contactor and a bottom socket outside the test site.

Embodiments of the present invention are directed to systems and methods for performing vision alignment using an offline vision assisted calibration station—i.e., a vision assisted calibration system located away from the test site.

The systems and methods disclosed herein are used for aligning double-sided IC devices, for example, IC devices with fine pitch dot array on the top side and standard pitch array on the bottom side. Top side fine pitch is typically less than 0.30 mm and standard bottom side pitch is greater than 0.30 mm. A top side contactor array is used to test the IC device top side array, while a bottom socket array is used to test the IC device bottom side array. To accurately align to the IC top fine pitch array to the top side contactor array, runtime vision alignment is used to physically align the top side IC array to the fixed top side contactor array. If the IC alignment between top and bottom are held to a tight tolerance, the bottom IC array is assumed to be in alignment with the top IC array. Therefore, the bottom socket array must be accurately aligned to the top contactor array. To remove any misalignments, an offline vision assisted calibration station is used to align the top contact array to the bottom socket array.

In one embodiment, an offline vision assisted calibration system includes: a bottom side socket assembly that is mountable in an integrated circuit device handler and comprises: a socket plate that comprises a hole grid array; and a top contactor assembly that is mountable in an integrated circuit device handler and comprises: a guide plate, a plurality of fiducials located on a lower side surface of the guide plate, a contact holder plate comprising a top contactor contact array, and a plurality of adjustment actuators configured to move the contact holder plate with respect to the guide plate; a calibration jig comprising an array of oversized contacts on a bottom side thereof, wherein the calibration jig is configured to be placed in the socket plate such that the oversized contacts engage with the hole grid array of the socket plate; a bottom side socket assembly holder configured to hold the bottom side socket assembly; and a top contactor assembly holder configured to hold the top contactor assembly.

In one aspect of the system, which is combinable with any combination of the above-mentioned aspects and embodiments of the system, one of the bottom side socket assembly or the top contactor assembly comprises a plurality of alignment pins; and the other of the bottom side socket assembly or the top contactor assembly comprises a plurality of bushings configured to engage with the alignment pins of the bottom side socket assembly.

In one aspect of the system, which is combinable with any combination of the above-mentioned aspects and embodiments of the system, the bottom side socket assembly further comprises a plurality of alignment pins located on an upper side surface of the socket plate; and the top contactor assembly further comprises a plurality of bushings located on a lower side surface of the guide plate, the bushings being configured to engage with the alignment pins of the bottom side socket assembly.

In one aspect of the system, which is combinable with any combination of the above-mentioned aspects and embodiments of the system, the top contactor assembly further comprises a plurality of alignment pins located on a lower side surface of the guide plate; and the bottom side socket assembly further comprises a plurality of bushings located on an upper side surface of the socket plate, the bushings being configured to engage with the alignment pins of the top contactor assembly.

In one aspect of the system, which is combinable with any combination of the above-mentioned aspects and embodiments of the system, the system further includes an upward facing camera; and a controller configured to: while the calibration jig is in the socket plate, cause the top contactor assembly holder to move the top contactor assembly to a position at which the alignment pins are engaged with the bushings, while the alignment pins are engaged with the bushings, cause the top contactor assembly holder to pick up the calibration jig from the bottom side socket assembly and move the calibration jig to a location above the upward-facing camera, receive, from the upward-facing camera, an image of a bottom side of the top contactor assembly and calibration jig, and determine, based on the received image, a first offset between the array of oversized contacts of the calibration jig and the fiducials of the top contactor assembly, the first offset being representative of an offset between the hole grid array of the bottom side socket assembly and the fiducials of the top contactor assembly.

In one aspect of the system, which is combinable with any combination of the above-mentioned aspects and embodiments of the system, the controller is further configured to: receive, from the upward-facing camera, an image of the bottom side of the top contactor assembly without the calibration jig, determine a second offset between the top contactor contact array and the fiducials of the top contactor assembly, and determine a third offset between the top contactor contact array and the hole grid array by calculating a difference between the first offset and the second offset.

In one aspect of the system, which is combinable with any combination of the above-mentioned aspects and embodiments of the system, the hole grid array comprises a plurality of holes, each of which contains a moveable pogo pin.

In one aspect of the system, which is combinable with any combination of the above-mentioned aspects and embodiments of the system, the plurality of bushings comprises a first bushing and a second bushing; the first bushing comprises a half-circular solid piece and a first plurality of spring loaded fingers configured to reference a respective alignment pin toward the half-circular solid piece; and the second bushing comprises a half-oval solid piece and a second plurality of spring loaded fingers configured to reference a respective alignment pin toward the half-oval solid piece.

In one aspect of the system, which is combinable with any combination of the above-mentioned aspects and embodiments of the system, the plurality of adjustment actuators comprises: a first adjustment actuator and a second adjustment actuator located at two positions along a first side of the contact holder plate and configured to move the contact holder plate with respect to the guide plate in an X-direction, and a second adjustment actuator located at a position along a second side of the contact holder plate, perpendicular to the first side, and configured to move the contact holder plate with respect to the guide plate in a Y-direction; and the first, second, and third adjustment actuators are further configured to adjust an angular position of the contact holder plate with respect to the guide plate.

In one aspect of the system, which is combinable with any combination of the above-mentioned aspects and embodiments of the system, the top contactor assembly first comprises: a first spring located opposite the first actuator and configured to bias the contact holder plate toward the first actuator, a second spring located opposite the second actuator and configured to bias the contact holder plate toward the second actuator, and a third spring located opposite the third actuator and configured to bias the contact holder plate toward the third actuator.

In one aspect of the system, which is combinable with any combination of the above-mentioned aspects and embodiments of the system, the top contactor contact array is a pogo array comprising a plurality of holes, each of which contains a pogo pin.

In one aspect of the system, which is combinable with any combination of the above-mentioned aspects and embodiments of the system, the contact holder plate further comprises an additional set of holes located inside or outside of the pogo array when viewed from below the contact holder plate, and the holes in the additional set of holes do not contain pogo pins.

In another embodiment, a method of performing offline vision assisted calibration includes: providing an offline vision assisted calibration system comprising: a bottom side socket assembly that is mountable in an integrated circuit device handler and comprises: a socket plate that comprises a hole grid array, a top contactor assembly that is mountable in an integrated circuit device handler and comprises: a guide plate, a plurality of fiducials located on the lower side surface of the guide plate, a contact holder plate comprising a top contactor contact array, and a plurality of adjustment actuators configured to move the contact holder plate with respect to the guide plate, a calibration jig comprising an array of oversized contacts on a bottom side thereof, wherein the calibration jig is configured to be placed in the socket plate such that the oversized contacts engage with the hole grid array of the socket plate, and a bottom side socket assembly holder configured to hold the bottom side socket assembly, a top contactor assembly holder configured to hold the top contactor assembly, and an upward-facing camera, wherein one of the bottom side socket assembly or the top contactor assembly comprises a plurality of alignment pins, and the other of the bottom side socket assembly or the top contactor assembly comprises a plurality of bushings configured to engage with the alignment pins of the bottom side socket assembly; while the calibration jig is in the socket plate, causing the top contactor assembly holder to move the top contactor assembly to a position at which the alignment pins are engaged with the bushings; while the alignment pins are engaged with the bushings, causing the top contactor assembly holder to pick up the calibration jig from the bottom side socket assembly and move the calibration jig to a location above the upward-facing camera; receiving, from the upward-facing camera, an image of a bottom side of the top contactor assembly and calibration jig; and determining, based on the received image; a first offset between the array of oversized contacts of the calibration jig and the fiducials of the top contactor assembly, the first offset being representative of an offset between the hole grid array of the bottom side socket assembly and the fiducials of the top contactor assembly.

In one aspect of the system, which is combinable with any combination of the above-mentioned aspects and embodiments of the method, the method further comprises receiving, from the upward-facing camera, an image of the bottom side of the top contactor assembly without the calibration jig; determining a second offset between the top contactor contact array and the fiducials of the top contactor assembly; and determining a third offset between the top contactor contact array and the hole grid array by calculating a difference between the first offset and the second offset.

In one aspect of the system, which is combinable with any combination of the above-mentioned aspects and embodiments of the system, the plurality of bushings comprises a first bushing and a second bushing; the first bushing comprises a half-circular solid piece and a first plurality of spring loaded fingers configured to reference a respective alignment pin toward the half-circular solid piece; and the second bushing comprises a half-oval solid piece and a second plurality of spring loaded fingers configured to reference a respective alignment pin toward the half-oval solid piece.

In another embodiment, a system for performing offline vision alignment between a socket and a contactor includes: a socket holder configured to hold a socket having a hole grid array; a jig comprising an array of jig contacts at its bottom surface, the jig contacts being configured to engage with holes of the hole grid array; a contactor holder configured to hold a contactor having an array of contactor contacts and at least one fiducial, and configured to cause the contactor to pick up the jig from the socket; an upward looking camera; and a controller configured to: receive data from the upward looking camera, determine a locational offset between the socket hole grid array and the at least one contactor fiducial based on an image taken by the upward looking camera of the contactor holding the jig, determine a locational offset between the contactor contacts and the at least one contactor fiducial based on an image taken by the upward looking camera of the contactor without the jig, and determine a locational offset between the contactor contacts and the socket hole grid array based on a difference between (i) the determined locational offset between the socket hole grid array and the at least one contactor fiducial and (ii) the determined locational offset between the contactor contacts and the at least one contactor fiducial.

### BRIEF DESCRIPTION OF THE DRAWINGS

Embodiments of the invention are described by referring to the attached drawings, in which:

FIG. 1 is a top perspective view of a double-sided IC device.

FIG. 2 is a top perspective view of a bottom socket with a hole grid array (“HGA”) and guide pins.

FIG. 3 is a bottom view of a top contactor with zero clearance bushings and extra pogo holes.

FIG. 4A is a top perspective view of circular bushing for maintaining a correct origin position.

FIG. 4B is a top perspective view of an oval bushing for maintaining a correct angular position.

FIG. 5 is a schematic view of an offline vision assisted calibration station.

In the drawings, like reference numerals are sometimes used to designate like structural elements. It should also be appreciated that the depictions in the figures are diagrammatic and not to scale.

### DETAILED DESCRIPTION

In the following description, for purposes of explanation and not limitation, details and descriptions are set forth in order to provide a thorough understanding of embodiments of the present invention. However, it will be apparent to those skilled in the art that the present invention may be practiced in other embodiments that depart from these details and descriptions.

### Double-Sided IC Devices

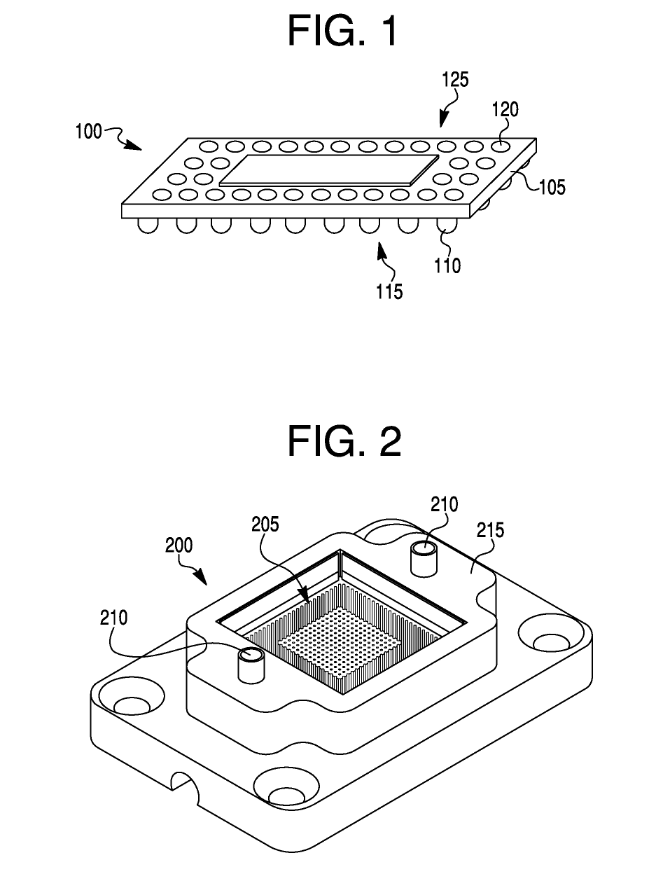

Embodiments of the systems and methods as disclosed herein may be used for aligning double-sided IC devices, for example, IC devices with fine pitch dot array on the top side and standard pitch array on the bottom side. Top side fine pitch is typically less than 0.30 mm and standard bottom side pitch is greater than 0.30 mm. One example of a double-sided IC device is the device 100 shown in FIG. 1. The double-sided IC device 100 shown in FIG. 1 is a POP device that includes an IC substrate 105. The bottom side array has solder balls 110 attached to the IC substrate, forming a ball grid array (BGA) 115. The top side IC array has flat circular pads 120 forming a land grid array (LGA) 125, but may alternatively have interposed BGA surfaces.

A top side contactor array is used to test the IC device top side array 125, while a bottom socket array is used to test the IC device bottom side array 115.

### Bottom Side Socket Assembly

An example of a bottom side socket assembly 200 is shown in FIG. 2. A hole grid array (HGA) 205 located in an HGA plate 215 (an example of a socket plate) is used to align the balls of the IC to the contact pins within the socket assembly 200. Each through-hole 207 (or “pogo hole”) in the HGA 205 has a pogo pin (not shown). There are two pins 210 on the bottom socket assembly 200 used to establish a common local coordinate system with the top contactor. In this embodiment, the alignment pins 210 are located on an upper side surface of the HGA plate 215 and are in a fixed position in relationship to the HGA 205.

Before top contacting, the pogo pin tips are more than one DUT bottom ball diameter below a top surface of the HGA 205. During top contacting, the HGA plate 215 engages the bottom side IC substrate 105 without touching the balls 110 to ensure that the top IC contact array 125 is engaged first so there is no lateral forces on the bottom side. After top contacting, bottom contact is established by moving the bottom pogo pins up to contact the balls 115 on the bottom of the IC device 100.

During calibration time, each IC top contactor is aligned to a corresponding bottom side socket assembly 200. The bottom side socket assembly 200 is calibrated in an offline calibration station with the top side contactor assembly. These match pairs can now be used in a handler for IC device testing.

### Top Contactor Assembly

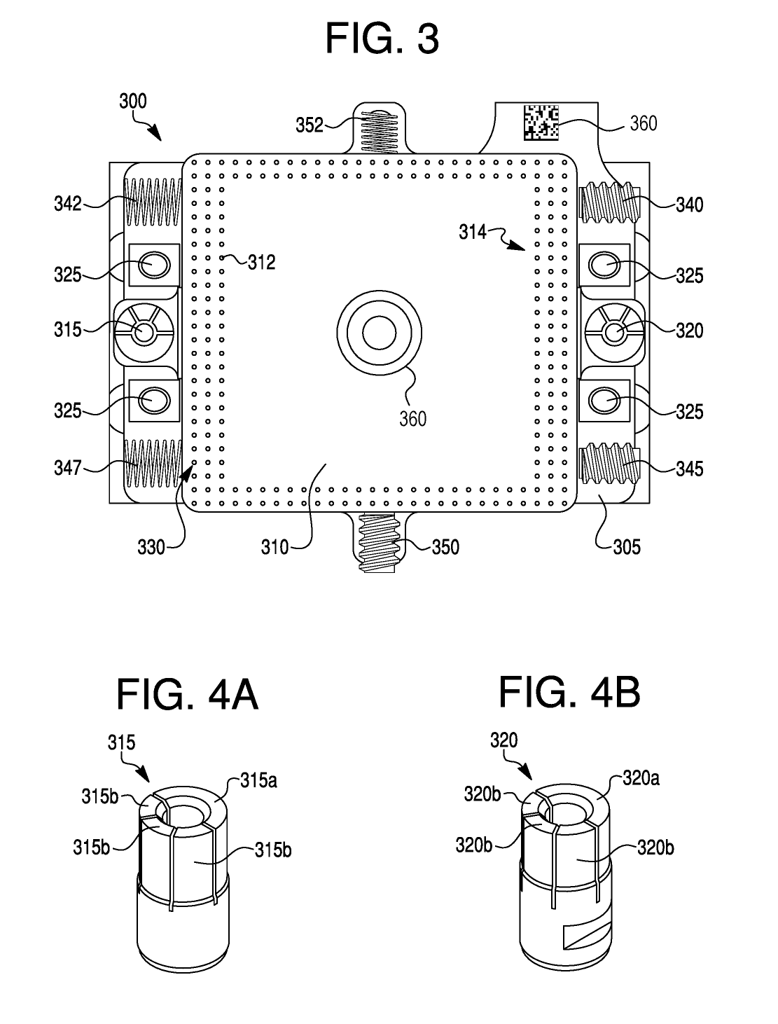

The top contactor assembly 300, shown in FIG. 3, has a guide plate 305 and a pogo holder plate 310. The pogo holder plate 310 (an example of a contact holder plate) includes a plurality of pogo holes 312 in which pogo pins are located, forming a pogo array 314 (an example of a top contactor contact array). The top contactor assembly 300 includes a first adjustment actuator 340 (X1 adjustment actuator), a second adjustment actuator 345 (X2 adjustment actuator), and a third adjustment actuator 350 (Y3 adjustment actuator). Opposite the first actuator 340 is a first spring 342 configured to bias the pogo holder plate 310 toward the first actuator 340. Opposite the second actuator 345 is a second spring 347 configured to bias the pogo holder plate 310 toward the second actuator 345. Opposite the third actuator 350 is a third spring 352 configured to bias the pogo holder plate 310 toward the third actuator 350. The adjustment actuators are configured to move the pogo holder plate 310 with respect to the guide plate 305. Thus, the X-position, Y-position, and angular position of the pogo holder plate 310 can be adjusted. As discussed in more detail below, the adjustment actuators 340, 345, 350 can be used during calibration to correct the offset between the contactor pogo array 314 and the socket HGA 205 to within a predetermined acceptable tolerance range. After calibration, the pogo holder plate 310 is locked in reference to the guide plate 305.

The contactor includes a vacuum port 365 configured to supply a vacuum for holding the jig during calibration and for holding semiconductor devices during testing.

Each top contactor also has two zero clearance bushings 315, 320. A first bushing 315, shown in FIG. 4A, contains a half circular solid piece 315a to determine the origin of the pin-bushing engagement local coordinate system. The other bushing 320, shown in FIG. 4B, has a half oval solid piece 320a used to determine the angle of the pin-bushing local coordinate. Both bushings have spring loaded fingers 315b, 320b to reference the pins 210 towards the half circular solid piece 315a and half oval solid piece 320a. Because the bushings 315, 320 do not have good lighting contrast for vision imaging, fiducials 325 are used to represent the pin-bushing local coordinate relationship on the guide plate 305. As long as the pin-bushing engagement is repeatable, the fiducial-to-bushing distance has no need to be measured.

Each top contactor pogo array plate 310 has an extra inner or outer set of holes 330. The extra holes 330 have the same dimensional and positional tolerances as the pogo holes 312 to simplify the manufacturing process. The extra holes 330 provide better contrast to locate the pogo array.

The top contactor assembly 300 includes an identification tag 360, which can be matched to a corresponding identification tag on the bottom side socket assembly 200 to help keep track of calibrated sets of bottom side socket assemblies 200 and top contactor assemblies 300.

### Offline Vision Assisted Calibration Station

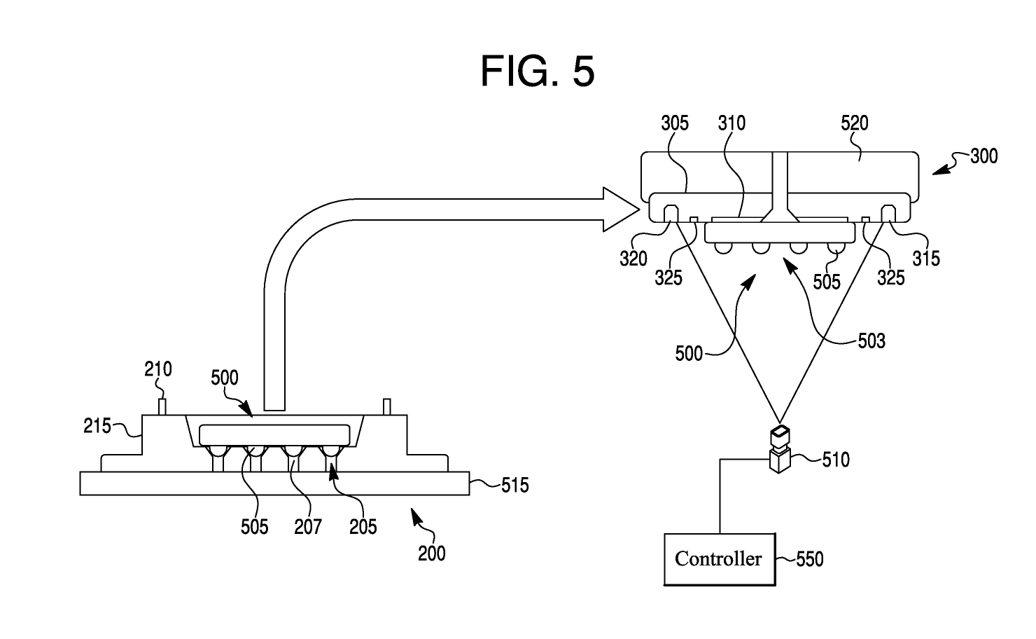

To accurately align to the IC top fine pitch array 125 to the top side contactor array 314, runtime vision alignment is used to physically align the top side IC array 125 to the fixed top side contactor array 314. Runtime vision alignment is performed at the test site of an IC device handler. If the IC alignment between top and bottom are held to a tight tolerance, the bottom IC array 115 is assumed to be in alignment with the top IC array 125. Therefore, the bottom socket array 205 must be accurately aligned to the top contactor array 314. To remove any misalignments, an offline vision assisted calibration station, shown in FIG. 5, is used to align the top contact array 314 to the bottom socket array 205 (i.e., calibrating the top contact array 314 to the bottom socket array 205). By “offline,” what it meant is that the vision assisted calibration station is located outside of the test site of the IC device handler, and that the calibration occurs before IC device testing is started.

A calibration jig 500 with oversized contacts is used for calibration. In this example, the calibration jig is a BGA jig 500 with a BGA 503 having oversized balls 505 (e.g., oversized solder balls) is used for the vision assisted calibration. In this application, the phrase “oversized contacts” or “oversized balls” means that the contacts and balls have a size larger than that of the contacts and balls of the typical IC device that is tested using the bottom side socket assembly 200 and top contactor assembly 300. For example, the size of the balls 505 of the BGA jig 500 may be slightly larger than the pogo holes 207. The BGA jig 500 is placed in the HGA 205 manually to ensure the balls 505 fit into the pogo holes 207 of the HGA 205. During calibration, the manually placed BGA jig 500 is picked up by the top contactor assembly 300 using vacuum. The position of the HGA 205 is represented by the location of the BGA jig 500 in the top contactor fiducial coordinate system.

The vision assisted calibration station includes an upward-looking camera (“ULC”) 510 used to assist in the calibration process. The vision assisted calibration station further includes a bottom socket assembly holder 515 configured to hold the bottom side socket assembly 200, and a top contactor assembly holder 520 configured to hold the top contactor assembly 300.

During a vision assisted calibration procedure, the bottom side socket assembly 200 is mounted into the bottom side socket assembly holder 515. The top contactor assembly 300 is mounted onto the top contactor assembly holder 520. The BGA jig 500 is manually placed into the socket HGA 205, such that the balls 505 are engaged with the holes 207. A controller 550, having a processor and memory, causes the top contactor assembly 300 to pick up the BGA jig 500 using vacuum, while the alignment pins 210 are engaged in the contactor bushings 315, 320. The controller then causes the top contactor assembly 300 to move the BGA jig 500 to a location above the ULC 510. Controlled by the controller 550, the ULC 510 views and captures an image of a bottom side of the top contactor assembly 300 holding the BGA jig 500, as shown in FIG. 5. The controller 550 receives data (e.g., image data) from the ULC 510, and determines an offset between the BGA 503 and the contactor fiducials 325. The offset between the HGA 205 and the contactor fiducials 325 can be determined by locating the BGA jig 500 in the top contactor fiducial coordinate system. More specifically, because the BGA 503 was aligned with the HGA 205 and the zero-clearance bushings 315, 320 of the top contactor assembly 300 were engaged with the alignment pins 210 of the bottom side socket assembly 200, the offset between the BGA 503 and the contactor fiducials 325 can be used to determine (and is, in fact, representative of and/or equivalent to) the offset between the HGA 205 and the contactor fiducials 325. The offset between the HGA 205 and the contactor fiducials 325 is saved for vision assisted correction.

After the above described calibration procedure is complete, the BGA jig 500 is removed, and a vision assisted correction procedure is performed. The ULC 510 views the top contactor assembly 300 directly. The controller 550 receives data from the ULC 510, and uses that data to determine the offset between the contactor pogo array 314 and the contactor fiducials 325. The controller 550 then determines the offset between the contactor pogo array 314 and the socket HGA 205, by calculating the difference between (i) the offset between the contactor pogo array 314 and the contactor fiducials 325, and (ii) the previously determined offset between the HGA 205 and the contactor fiducials 325. The X1, X2, Y3 adjustment actuators 340, 345, 350 are used to correct the offset between the contactor pogo array 314 and the socket HGA 205 to within a predetermined acceptable tolerance range. After calibration, the pogo holder plate 310 is locked in reference to the guide plate 305. Then, both the top contactor assembly 300 and the bottom side socket assembly 200 are mounted in an IC device test handler for runtime use.

In alterative embodiments, the contactor bushings 320, 325 can be changed to contactor pins, and the socket pins 210 can be changed to socket bushings.

### Advantages

The offline vision assisted calibration can be used to detect the top contactor to match the bottom socket position due to mechanical tolerance stack. The offline vision assisted adjustment can be used to correct the stacked mechanical errors between the top contactor and the bottom socket position. By correcting the mechanical tolerance stack, smaller pitch contact is achievable.

The offline vision assisted calibration provides advantages over the use of mechanical tight tolerances to ensure the bottom socket matches the top contactor position. If mechanical tight tolerances are used, all the parts related to the matching must have very tight tolerances. Because so many parts are related to the matching, manufacturability decreases and cost increases. Using the offline vision assisted calibration for the match, the mechanical errors will be calibrated out. Therefore, no tight mechanical tolerances are required.

The offline vision assisted calibration provides advantages over calibration at the test site of the IC testing handler. The test site of the IC test handler usually is very crowded. There is almost no space to make the adjustment for the calibration. The zero clearance pin-bushing engagement defines the local coordinate for the top contactor to the bottom socket matching. Offline space is much larger than the space in machine. It is also possible to have better lighting to make the detection more accurate and repeatable with the offline calibration than an in-machine vision calibration. Multiple vision detections and adjustments for accuracy and repeatability can be more easily performed with the offline calibration than an in-machine calibration. Further, in-machine calibration uses valuable machine time, while offline calibration will do the most work offline to save machine time. Additionally, troubleshooting is performed more easily in the offline vision assisted calibration station than at the test site. Finally, in-machine calibration may need multiple cameras and adjustment mechanisms for each machine, which increases cost. Because the offline calibration station, including the camera and lighting, can be reused for many test sites on many handlers, cost can be lowered.

The foregoing description of embodiments has been presented for purposes of illustration and description. The foregoing description is not intended to be exhaustive or to limit embodiments of the present invention to the precise form disclosed, and modifications and variations are possible in light of the above teachings or may be acquired from practice of various embodiments. The embodiments discussed herein were chosen and described in order to explain the principles and the nature of various embodiments and its practical application to enable one skilled in the art to utilize the present invention in various embodiments and with various modifications as are suited to the particular use contemplated. The features of the embodiments described herein may be combined in all possible combinations of methods, apparatus, modules, systems, and computer program products.

What is claimed is:

1. An offline vision assisted calibration system comprising:
a bottom side socket assembly that is mountable in an integrated circuit device handler and comprises:
a socket plate that comprises a hole grid array; and
a top contactor assembly that is mountable in an integrated circuit device handler and comprises:
a guide plate,
a plurality of fiducials located on a lower side surface of the guide plate,
a contact holder plate comprising a top contactor contact array, and
a plurality of adjustment actuators configured to move the contact holder plate with respect to the guide plate;
a calibration jig comprising an array of contacts on a bottom side thereof, wherein the calibration jig is configured to be placed in the socket plate such that the contacts engage with the hole grid array of the socket plate;
a bottom side socket assembly holder configured to hold the bottom side socket assembly; and
a top contactor assembly holder configured to hold the top contactor assembly.

2. The system of claim 1, wherein:
one of the bottom side socket assembly or the top contactor assembly comprises a plurality of alignment pins; and
the other of the bottom side socket assembly or the top contactor assembly comprises a plurality of bushings configured to engage with the alignment pins of the bottom side socket assembly.

3. The system of claim 2, wherein:
the bottom side socket assembly further comprises a plurality of alignment pins located on an upper side surface of the socket plate; and
the top contactor assembly further comprises a plurality of bushings located on a lower side surface of the guide plate, the bushings being configured to engage with the alignment pins of the bottom side socket assembly.

4. The system of claim 2, wherein:
the top contactor assembly further comprises a plurality of alignment pins located on a lower side surface of the guide plate; and
the bottom side socket assembly further comprises a plurality of bushings located on an upper side surface of the socket plate, the bushings being configured to engage with the alignment pins of the top contactor assembly.

5. The system of claim 2, further comprising:
an upward facing camera; and
a controller configured to:
while the calibration jig is in the socket plate, cause the top contactor assembly holder to move the top contactor assembly to a position at which the alignment pins are engaged with the bushings,
while the alignment pins are engaged with the bushings, cause the top contactor assembly holder to pick up the calibration jig from the bottom side socket assembly and move the calibration jig to a location above the upward-facing camera,
receive, from the upward-facing camera, an image of a bottom side of the top contactor assembly and calibration jig, and
determine, based on the received image, a first offset between the array of contacts of the calibration jig and the fiducials of the top contactor assembly, the first offset being representative of an offset between the hole grid array of the bottom side socket assembly and the fiducials of the top contactor assembly.

6. The system of claim 5, wherein:
the controller is further configured to:
receive, from the upward-facing camera, an image of the bottom side of the top contactor assembly without the calibration jig,
determine a second offset between the top contactor contact array and the fiducials of the top contactor assembly, and
determine a third offset between the top contactor contact array and the hole grid array by calculating a difference between the first offset and the second offset.

7. The system of claim 1, wherein the hole grid array comprises a plurality of holes, each of which contains a moveable pogo pin.

8. The system of claim 2, wherein:
the plurality of bushings comprises a first bushing and a second bushing;
the first bushing comprises a half-circular solid piece and a first plurality of spring loaded fingers configured to reference a respective alignment pin toward the half-circular solid piece; and
the second bushing comprises a half-oval solid piece and a second plurality of spring loaded fingers configured to reference a respective alignment pin toward the half-oval solid piece.

9. The system of claim 1, wherein:
the plurality of adjustment actuators comprises:
a first adjustment actuator and a second adjustment actuator located at two positions along a first side of the contact holder plate and configured to move the contact holder plate with respect to the guide plate in an X-direction, and
a second adjustment actuator located at a position along a second side of the contact holder plate, perpendicular to the first side, and configured to move the contact holder plate with respect to the guide plate in a Y-direction; and
the first, second, and third adjustment actuators are further configured to adjust an angular position of the contact holder plate with respect to the guide plate.

10. The system of claim 9, wherein:
the top contactor assembly first comprises:
a first spring located opposite the first actuator and configured to bias the contact holder plate toward the first actuator,
a second spring located opposite the second actuator and configured to bias the contact holder plate toward the second actuator, and
a third spring located opposite the third actuator and configured to bias the contact holder plate toward the third actuator.

11. The system of claim 1, wherein the top contactor contact array is a pogo array comprising a plurality of holes, each of which contains a pogo pin.

12. The system of claim 8, wherein the contact holder plate further comprises an additional set of holes located inside or outside of the pogo array when viewed from below the contact holder plate, and the holes in the additional set of holes do not contain pogo pins.

13. A method of performing offline vision assisted calibration, the method comprising:
providing an offline vision assisted calibration system comprising:
a bottom side socket assembly that is mountable in an integrated circuit device handler and comprises:
a socket plate that comprises a hole grid array.
a top contactor assembly that is mountable in an integrated circuit device handler and comprises:
a guide plate,
a plurality of fiducials located on the lower side surface of the guide plate,
a contact holder plate comprising a top contactor contact array, and
a plurality of adjustment actuators configured to move the contact holder plate with respect to the guide plate,
a calibration jig comprising an array of contacts on a bottom side thereof, wherein the calibration jig is configured to be placed in the socket plate such that the contacts engage with the hole grid array of the socket plate,
a bottom side socket assembly holder configured to hold the bottom side socket assembly,
a top contactor assembly holder configured to hold the top contactor assembly, and
an upward-facing camera,
wherein one of the bottom side socket assembly or the top contactor assembly comprises a plurality of alignment pins, and the other of the bottom side socket assembly or the top contactor assembly comprises a plurality of bushings configured to engage with the alignment pins of the bottom side socket assembly;
while the calibration jig is in the socket plate, causing the top contactor assembly holder to move the top contactor assembly to a position at which the alignment pins are engaged with the bushings;
while the alignment pins are engaged with the bushings, causing the top contactor assembly holder to pick up the calibration jig from the bottom side socket assembly and move the calibration jig to a location above the upward-facing camera;
receiving, from the upward-facing camera, an image of a bottom side of the top contactor assembly and calibration jig; and
determining, based on the received image; a first offset between the array of contacts of the calibration jig and the fiducials of the top contactor assembly, the first offset being representative of an offset between the hole grid array of the bottom side socket assembly and the fiducials of the top contactor assembly.

14. The method of claim 13, further comprising:
receiving, from the upward-facing camera, an image of the bottom side of the top contactor assembly without the calibration jig;
determining a second offset between the top contactor contact array and the fiducials of the top contactor assembly; and
determining a third offset between the top contactor contact array and the hole grid array by calculating a difference between the first offset and the second offset.

15. The method of claim 13, wherein:
the plurality of bushings comprises a first bushing and a second bushing;
the first bushing comprises a half-circular solid piece and a first plurality of spring loaded fingers configured to reference a respective alignment pin toward the half-circular solid piece; and
the second bushing comprises a half-oval solid piece and a second plurality of spring loaded fingers configured to reference a respective alignment pin toward the half-oval solid piece.

16. A system for performing offline vision alignment between a socket and a contactor, the system comprising:
a bottom side socket assembly holder configured to hold a bottom side sock assembly having a hole grid array;
a calibration jig comprising an array of jig contacts at its bottom surface, the jig contacts being configured to engage with holes of the hole grid array;
a top contactor assembly holder configured to hold a top contactor assembly having an array of contactor contacts and a plurality of fiducials, and configured to cause the top contactor assembly to pick up the calibration jig from the bottom side socket assembly;
an upward-looking camera; and
a controller configured to:
receive data from the upward-looking camera,
determine a locational offset between the hole grid array and the contactor fiducials based on an image taken by the upward-looking camera of the top contactor assembly holding the calibration jig,
determine a locational offset between the contactor contacts and the contactor fiducials based on an image taken by the upward-looking camera of the top contactor assembly without the calibration jig, and
determine a locational offset between the contactor contacts and the socket hole grid array based on a difference between (i) the determined locational offset between the hole grid array and the contactor fiducials and (ii) the determined locational offset between the contactor contacts and the contactor fiducials.
